(19) United States
(12) Patent Application Publication
(10) Pub. No.: US 2015/0366077 A1
(43) Pub. Date: Dec. 17, 2015

(54) METHOD FOR PRODUCING MOUNTED STRUCTURE

(71) Applicant: KYOCERA CORPORATION, Kyoto-shi, Kyoto (JP)

(72) Inventors: Shinya KAWAI, Kirishima-shi (JP); Katsura HAYASHI, Kirishima-shi (JP)

(73) Assignee: KYOCERA CORPORATION, Kyoto-shi, Kyoto (JP)

(21) Appl. No.: 14/764,091

(22) PCT Filed: Dec. 21, 2013
(86) PCT No.: PCT/JP2013/084382

§ 371 Date: Jul. 28, 2015

(30) Foreign Application Priority Data
Jan. 30, 2013 (JP) 2013-015366

(51) Int. Cl. H05K 3/30; H05K 3/46

(52) U.S. Cl. CPC H05K 3/301; H05K 3/4644

(57) ABSTRACT

A method for producing a mounted structure according to an embodiment of the present invention includes a step of forming a circuit substrate, which includes an insulation layer and a conductive layer, on a support member by alternately stacking the insulation layer and the conductive layer on the support member; a step of forming a mounted structure, which includes the circuit substrate and an electronic component, on the support member by mounting the electronic component on the circuit substrate; and a step of removing the support member from the mounted structure. As a result, the efficiency in producing the mounted structure can be increased.

### TECHNICAL FIELD

The present invention relates to a method for producing a mounted structure that is used for electronic apparatuses (such as audio-visual apparatuses, household electrical appliances, telecommunication apparatuses, computers, and computer peripherals).

### BACKGROUND ART

To date, mounted structures including a circuit substrate and an electronic component mounted on the circuit substrate have been used for electronic apparatuses.

For example, Japanese Unexamined Patent Application Publication No. 2006-196925 describes a method for producing a circuit substrate. The method includes a step of forming a stack, in which an insulation layer (insulation layer) and a wiring pattern (conductive layer) are alternately stacked, on a core substrate (support member); and a step of peeling the stack from the core substrate and forming a circuit substrate by performing a desired treatment on the stack. A mounted structure can be made by mounting an electronic component on the circuit substrate obtained in such a way.

The thermal expansion coefficients of a circuit substrate and an electronic component differ from each other. Therefore, if heat is applied to the circuit substrate and the electronic component when mounting the electronic component on the circuit substrate, a thermal stress may be applied to the circuit substrate after mounting, and the circuit substrate may become warped. As a result, a faulty electrical connection between the circuit substrate and the electronic component may occur when making a mounted structure and the efficiency in producing the mounted structure is likely to decrease.

In particular, as electronic apparatuses have been reduced in size in recent years, reduction in the thickness of circuit substrates is required. However, when the thickness of circuit substrates is reduced, the circuit substrates become more likely to become warped, and therefore the efficiency in producing mounted structures is more likely to decrease.

### SUMMARY OF INVENTION

The present invention provides a method for producing a mounted structure with high production efficiency.

A method for producing a mounted structure according to an embodiment of the present invention includes a step of forming a circuit substrate, which includes an insulation layer and a conductive layer, on a support member by alternately stacking the insulation layer and the conductive layer on the support member; a step of forming a mounted structure, which includes the circuit substrate and an electronic component, on the support member by mounting the electronic component on the circuit substrate; and a step of removing the support member from the mounted structure.

The method for producing a mounted structure according to an embodiment of the present invention can reduce the occurrence of a faulty electrical connection between the circuit substrate and the electronic component and can increase the efficiency in producing the mounted structure.

### BRIEF DESCRIPTION OF DRAWINGS

FIG. 1(a) is a sectional view of a mounted structure according to a first embodiment of the present invention, which is cut in a thickness direction; FIG. 1(b) is an enlarged sectional view showing a region R1 of FIG. 1(a); and FIG. 1(c) is an enlarged sectional view showing a region R2 of FIG. 1(b).

FIGS. 2(a) to 2(d) are sectional views illustrating the process of producing the mounted structure shown in FIG. 1(a).

FIGS. 3(a) to 3(c) are sectional views illustrating the process of producing the mounted structure shown in FIG. 1(a).

FIGS. 4(a) and 4(b) are sectional views illustrating the process of producing the mounted structure shown in FIG. 1(a).

FIGS. 5(a) to 5(c) are sectional views illustrating the process of producing the mounted structure shown in FIG. 1(a).

FIG. 6 is a sectional view illustrating the process of producing a mounted structure according to a second embodiment of the present invention.

FIG. 7 is a sectional view illustrating the process of producing the mounted structure according to the second embodiment of the present invention.

FIG. 8 is a sectional view illustrating the process of producing a mounted structure according to a third embodiment of the present invention.

FIG. 9 is a sectional view illustrating the process of producing the mounted structure according to the third embodiment of the present invention.

FIG. 10 is a sectional view illustrating the process of producing the mounted structure according to the third embodiment of the present invention.

### DESCRIPTION OF EMBODIMENTS

### First Embodiment

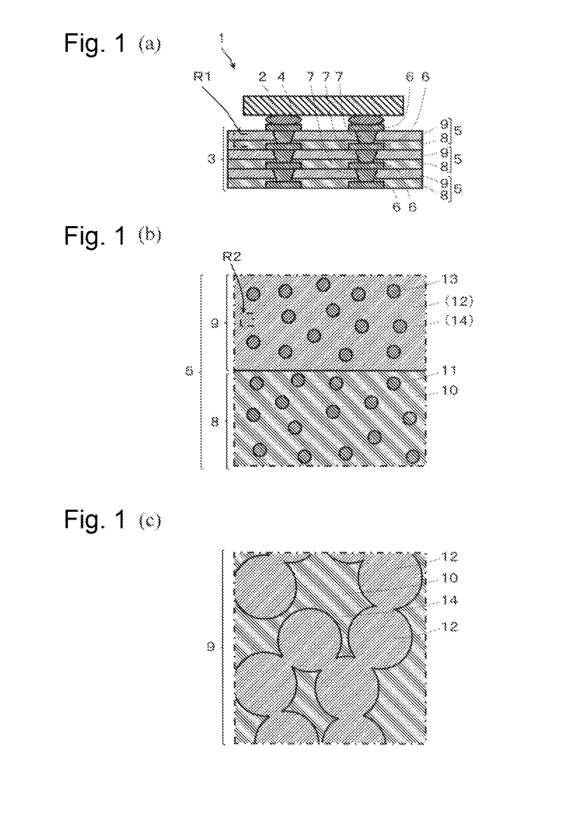

Hereinafter, referring to FIG. 1, a mounted structure, which is obtained by using a method for producing a mounted structure according to a first embodiment of the present invention, will be described in detail.

A mounted structure 1 shown in FIG. 1(a) is used, for example, for electronic apparatuses, such as audio-visual apparatuses, household electrical appliances, telecommunication apparatuses, computers, and computer peripherals. The mounted structure 1 includes an electronic component 2 and a circuit substrate 3 on which the electronic component 2 is mounted. In the mounted structure 1, the electronic component 2 is flip chip mounted on one main surface of the circuit substrate 3 via a bump 4, which is made of an electroconductive material, such as solder. The mounted structure 1 is mounted on an external circuit (not shown), such as a motherboard or the like, via a solder ball (not shown) or the like on the other main surface of the circuit substrate 3.

For example, the electronic component 2 is a semiconductor device, such as an IC or an LSI; an elastic wave device, such as a surface acoustic wave (SAW) device or a thin-film bulk acoustic resonator (FBAR); or the like. The electronic component 2 is sealed on the circuit substrate 3 with, for example, a sealing resin (not shown), such as an epoxy resin or a cyanate resin. The thickness of the electronic component 2 is, for example, 0.1 mm or larger and 1 mm or smaller. The thermal expansion coefficient of the electronic component 2 is, for example, 2 ppm/° C. or larger and 14 ppm/° C. or smaller. The thermal expansion coefficient of the electronic component 2 is measured in accordance with JIS K7197-1991 by using a commercially available TMA (Thermo-Mechanical Analysis) apparatus. The thermal expansion coefficient of each of the members described below is measured in the same way as the electronic component 2.

The circuit substrate 3 electrically connects the electronic component 2 to an external circuit while supporting the electronic component 2. The circuit substrate 3 includes insulation layers 5 and conductive layers 6, which are alternately stacked; and via conductors 7, which extend through the insulation layers 5 in the thickness direction and are electrically connected to the conductive layers 6. The circuit substrate 3 is, for example, a coreless substrate, which does not include a core substrate, such as a glass epoxy substrate. As a result, due to the absence of a core substrate, which has a large thickness, the circuit substrate 3 can be reduced in thickness and electronic apparatuses can be reduced in size. Moreover, due to the absence of a core substrate, which tends to reduce transmission characteristics for high-frequency signals, the electric characteristics of the circuit substrate 3 can be improved. Furthermore, it is not necessary that the number of the conductive layers 6 be an even number and the conductive layers 6 be disposed vertically symmetrically with a core substrate therebetween. Therefore, the number of the conductive layers 6 may be an odd number, and the circuit substrate 3 can be reduced in thickness. Preferably, the thickness of the circuit substrate 3 is, for example, 30 μm or larger and 200 μm or smaller, and more preferably, 100 μm or smaller.

The insulation layers 5 serve as insulators between the conductive layers 6 that are separated from each other in the thickness direction or in the main surface direction or as insulators between the via conductors 7 that are separated from each other in the main surface direction. The details of the insulation layers 5 will be described below.

The conductive layers 6, which are separated from each other in the thickness direction or in the main surface direction, function as wiring, such as ground wiring, power supply wiring, or signal wiring. The conductive layers 6 are made of a conductive material, such as copper. The outermost one of the conductive layers 6 includes a pad, to which the electronic component 2 or an external circuit is to be connected. A coating, such as a nickel coating or a gold coating, may be formed on a surface of the pad. The circuit substrate 3 according to the present embodiment includes four conductive layers 6. The thickness of each conductive layer 6 is, for example, 3 μm or larger and 20 μm or smaller. The thermal expansion coefficient of each conductive layer 6 is, for example, 14 ppm/° C. or larger and 18 ppm/° C. or smaller.

The via conductors 7 electrically connect the conductive layers 6 that are separated from each other in the thickness direction. The via conductors 7 are made of a material similar to that of the conductive layers 6 and have characteristics similar to those of the conductive layers 6. The via conductors 7 each have a tapered shape whose width decreases in a direction away from the electronic component 2. The width (diameter) of each via conductor 12 is, for example, 10 μm or larger and 75 μm or smaller.

Next, the insulation layers 5 will be described in detail.

Each insulation layer 5 includes a resin layer 8, which is disposed on the side opposite to the electronic component 2 side, and an inorganic insulation layer 9, which is disposed on the electronic component 2 side. The conductive layer 6 is partially disposed on one main surface of the inorganic insulation layer 9 on the electronic component 2 side, and the resin layer 8 surrounds a side surface and one main surface of the conductive layer 6 on the electronic component 2 side. The circuit substrate 3 according to the present embodiment includes three insulation layers 5.

The resin layer 8 bonds the inorganic insulation layers 9 to each other and also functions as an insulator between the conductive layers 6 that are separated from each other in the main surface direction. The resin layer 8 has a Young's modulus lower than that of the inorganic insulation layer 9 and can be elastically deformed more easily than the inorganic insulation layer 9. Therefore, the resin layer 8 functions to suppress the occurrence of cracking of the circuit substrate 3. The thickness of the resin layer 8 is, for example, 3 μm or larger and 30 μm or smaller. The thermal expansion coefficient of the resin layer 8 is, for example, 20 ppm/° C. or larger and 50 ppm/° C. or smaller. The Young's modulus of the resin layer 8 is, for example, 0.2 GPa or higher and 20 GPa or lower. The Young's modulus of the resin layer 8 is measured in accordance with ISO14577-1:2002 by using Nanoindenter XP made by MTS Systems Co. The Young's modulus of each of the members described below is measured in the same way as the resin layer 8.

As illustrated in FIG. 1(b), the resin layer 8 includes a resin 10 and a plurality of filler particles 11 dispersed in the resin 10.

A thermosetting resin, such as epoxy resin, bismaleimide triazine resin, cyanate resin, polyphenylene ether resin, wholly aromatic polyamide resin, or polyimide resin, can be used as the resin 10. The Young's modulus of the resin 10 is, for example, 0.1 GPa or higher and 5 GPa or lower. The thermal expansion coefficient of the resin 10 is, for example, 20 ppm/° C. or larger and 50 ppm/° C. or smaller.

The filler particles 11 are made of an inorganic insulating material, such as silicon oxide, aluminum oxide, aluminum nitride, aluminum hydroxide, or calcium carbonate. The average particle diameter of the filler particles 11 is, for example, 0.5 μm or larger and 5 μm or smaller. The thermal expansion coefficient of the filler particles 11 is, for example, 0 ppm/° C. or larger and 15 ppm/° C. or smaller. The proportion of the filler particles 11 in the resin layer 8 is, for example, 3 volume % or higher and 60 volume % or lower. The average particle diameter of the filler particles 11 can be measured by calculating the average value of the particle diameters of the filler particles 11 in a sectional plane extending in the thickness direction of the circuit substrate 3. The proportion (volume %) of the filler particles 11 in the resin layer 8 can be measured by regarding the ratio of the areas of the filler particles 11 to the area of the resin layer 8 in a sectional plane extending in the thickness direction of the circuit substrate 3 as the proportion. The average particle diameter and the proportion of each of the members described below are measured in the same way as the filler particles 11.

The inorganic insulation layer 9 increases the rigidity of the insulation layer 5 and decreases the thermal expansion coefficient of the insulation layer 5, thereby increasing the rigidity of the circuit substrate 3 and decreasing the difference between the thermal expansion coefficients of the electronic component 2 and the circuit substrate 3. As a result, when the electronic component 2 is activated and heat is applied to the mounted structure 1, the warping of the circuit substrate 3, which may occur due to the difference between the thermal expansion coefficients of the electronic component 2 and the circuit substrate 3, can be reduced. Therefore, the reliability of the connection between the electronic component 2 and the circuit substrate 3 can be increased, and thereby the electrical reliability of the mounted structure 1 can be increased. In particular, in a case where the circuit substrate 3 is reduced in thickness, the warping of the circuit substrate 3 can be effectively reduced, and the electrical reliability of the mounted structure 1 can be increased.

The thickness of the inorganic insulation layer 9 is, for example, 3 μm or larger and 30 μm or smaller. The Young's modulus of the inorganic insulation layer 9 is, for example, 10 GPa or higher and 50 GPa or lower. The thermal expansion coefficient of the inorganic insulation layer 9 is, for example, 0 ppm/° C. or larger and 10 ppm/° C. or smaller.

As illustrated in FIGS. 1(b) and 1(c), the inorganic insulation layer 9 includes a plurality of inorganic insulation particles 12 and 13, whose parts are connected to each other. The inorganic insulation particles 12 and 13 include a plurality of first inorganic insulation particles 12, whose parts are connected to each other; and a plurality of second inorganic insulation particles 13, which have particle diameters larger than those of the first inorganic insulation particles 12, whose parts are connected to the first inorganic insulation particles 12, and which are separated from each other with the first inorganic insulation particles 12 therebetween. A gap 14, which is an open pore, is formed between the first inorganic insulation particles 12. In other words, the inorganic insulation layer 9 is a porous body and has a three-dimensional mesh structure in which the inorganic insulation particles 12 and 13 are connected to each other. Connection portions between the inorganic insulation particles 12 and 13 are narrow and have a neck-like structure. In the inorganic insulation layer 9, the inorganic insulation particles 12 and 13, which are connected to each other and constrain each other, do not move easily in contrast to the filler particles 11, which are dispersed in the resin layer 8. Therefore, the rigidity of the inorganic insulation layer 9 can be increased and the thermal expansion coefficient of the inorganic insulation layer 9 can be reduced.

The first inorganic insulation particles 12 function as connection members in the inorganic insulation layer 9. The first inorganic insulation particles 12 are made of an inorganic insulating material, such as silicon oxide, aluminum oxide, boron oxide, magnesium oxide, or calcium oxide. In particular, silicon oxide is preferably used in view of low thermal expansion coefficient and low dielectric loss tangent. In this case, the first inorganic insulation particles 12 may include silicon oxide with a mass fraction of 90% or higher. Preferably, silicon oxide in an amorphous state is used in order to reduce the anisotropy of thermal expansion coefficient due to a crystal structure.

Each first inorganic insulation particle 12 is, for example, spherical. The average particle diameter of the first inorganic insulation particles 12 is, for example, 3 nm or larger and 110 nm or smaller. Because the particle diameters of the first inorganic insulation particles 12 are very small, the inorganic insulation layer 9 can be made dense and to have a high rigidity and a low thermal expansion coefficient, and the first inorganic insulation particles 12 can be easily connected to each other when making the inorganic insulation layer 9 as described below.

The second inorganic insulation particles 13, which have large particle diameters, increase the energy needed by a crack formed in the inorganic insulation layer 9 to circumvent the second inorganic insulation particles 13. Thus, extension of the crack can be suppressed. The second inorganic insulation particles 13 may be made of a material similar to that of the first inorganic insulation particles 12. In particular, in order to make the material characteristics of the second inorganic insulation particles 13 close to those of the first inorganic insulation particles 12, preferably, the second inorganic insulation particles 13 are made of a material the same as that of the first inorganic insulation particles 12. Each second inorganic insulation particles 13 is, for example, spherical. The average particle diameter of the second inorganic insulation particles 13 is, for example, 0.5 μm or larger and 5 μm or smaller. Because the second inorganic insulation particles 13 have large particle diameters as described above, extension of a crack formed in the inorganic insulation layer 9 can be effectively suppressed.

The gap 14, which is an open pore, has an opening 20 in the other main surface of the inorganic insulation layer 9. Because the inorganic insulation layer 9 is a porous body and has a three-dimensional mesh structure, at least a part of the gap 14 is surrounded by the inorganic insulation particles 12 and 13 in a sectional plane extending in the thickness direction of the inorganic insulation layer 9. A part of the resin layer 8, which is located on a side of the inorganic insulation layer 9 opposite to the electronic component 2 side, is disposed in the gap 14. In particular, a part of the resin 10 is disposed in the gap 14. As a result, the resin 10, which can be elastically deformed easily, reduces a stress applied to the inorganic insulation layer 9, and therefore the occurrence of cracking in the inorganic insulation layer 9 can be suppressed. Moreover, the strength of bonding the inorganic insulation layer 9 and the resin layer 8 can be increased due to an anchor effect. The proportion of the gap 14 in the inorganic insulation layer 9 and the gap 14 is, for example, 10 volume % or higher and 50 volume % or lower.

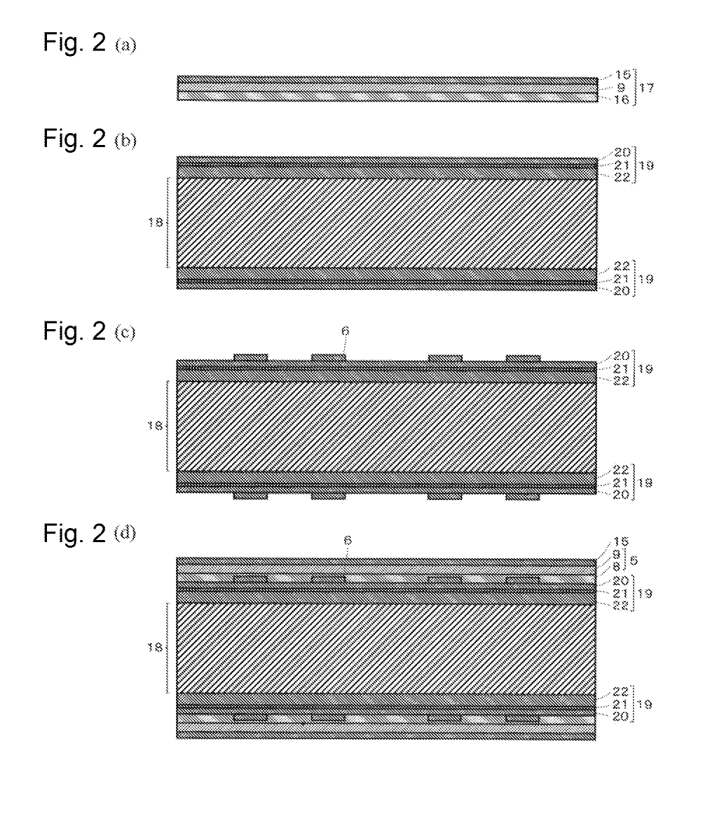

Next, referring to FIGS. 2 to 5, a method for producing the mounted structure 1 will be described.

(1) As illustrated in FIG. 2(a), a stack sheet 17, which includes a support sheet 15, the inorganic insulation layer 9 disposed on the support sheet 15, and an uncured resin layer precursor 16 disposed on the inorganic insulation layer 9, is made. To be specific, this is performed, for example, as follows.

First, the support sheet 15 and an inorganic insulation sol, which includes the inorganic insulation particles 12 and 13 and a solvent in which these particles are dispersed, are prepared; and the inorganic insulation sol is applied to one main surface of the support sheet 15. Next, the solvent of the inorganic insulation sol is evaporated so that the inorganic insulation particles 12 and 13 remain on the support sheet 15. The remaining inorganic insulation particles 12 and 13 are in contact with each other at adjacent positions. Next, the inorganic insulation particles 12 and 13 are heated, and the inorganic insulation particles 12 and 13 located adjacent to each other are made to be connected to each other at adjacent positions, thereby forming the inorganic insulation layer 9. Next, the resin layer precursor 16 is stacked on the inorganic insulation layer 9; the stack of the inorganic insulation layer 9 and the resin layer precursor 16 is heated and pressed in the thickness direction, so that the gap 14 is filled with a part of the resin layer precursor 16. As a result, the stack sheet 17 can be made.

As the support sheet 15, for example, a metal foil, such as a copper foil, or a resin film, such as a PET film, can be used. The thickness of the support sheet 15 is, for example, 12 μm or larger and 200 μm or smaller.

The proportion of the inorganic insulation particles 12 and 13 in the inorganic insulation sol is, for example, 10 volume % or higher and 50 volume % or lower. The proportion of the solvent in the inorganic insulation sol is, for example, 50 volume % or higher and 90 volume % or lower. Examples of the solvent include methanol, isopropanol, n-butanol, ethylene glycol, ethylene glycol monopropyl ether, methyl ethyl ketone, methyl isobutyl ketone, xylene, propylene glycol monomethyl ether, propylene glycol monomethyl ether acetate, dimethylacetamide, and an organic solvent including a mixture of two or more of these materials.

The inorganic insulation sol is dried by, for example, heating and air-drying. The drying temperature is, for example, 20° C. or higher and lower than the boiling point of the solvent 26, and the drying time is, for example, 20 seconds or longer and 30 minutes or shorter.

The heating temperature when connecting the inorganic insulation particles 12 and 13 to each other is higher than or equal to the boiling point of the solvent and lower than the crystallization temperature of the inorganic insulation particles 12 and 13. Preferably, the heating temperature is 100° C. or higher and 250° C. or lower. The heating time is, for example, 0.5 hours or longer and 24 hours or shorter. The first inorganic insulation particles 12, having an average particle diameter of 3 nm or larger and 110 nm or smaller as described above, are very small. Therefore, even at such a low temperature, the first inorganic insulation particles 12 can be firmly connected to each other, and the first inorganic insulation particles 12 and the second inorganic insulation particles 13 can be firmly connected to each other. The reason for this is estimated as follows. Because the first inorganic insulation particles 12 are very small, the atoms of the first inorganic insulation particles 12, in particular, the atoms at the surfaces move actively. Therefore, even under such a low temperature, the first inorganic insulation particles 12 are firmly connected to each other and the first inorganic insulation particles 12 and the second inorganic insulation particles 13 are firmly connected to each other.

Moreover, by heating the inorganic insulation particles 12 and 13 at such a low temperature, the first inorganic insulation particles 12 can be connected to each other and the first inorganic insulation particles 12 and the second inorganic insulation particles 13 can be connected to each other only in adjacent regions, while maintaining the particulate shapes of the first inorganic insulation particles 12 and the second inorganic insulation particles 13. As a result, the gap 14, which is an open pore, can be easily formed. The temperature at which the first inorganic insulation particles 12 can be firmly connected to each other is, for example, about 250° C. in a case where the average particle diameter of the first inorganic insulation particles 12 is 110 nm or smaller and about 150° C. in a case where the average particle diameter of the first inorganic insulation particles 12 is 15 nm or smaller.

When heating and pressing the stack of the inorganic insulation layer 9 and the resin layer precursor 16, the pressure is, for example, 0.5 MPa or higher and 2 MPa or lower; the pressing time is, for example, 60 seconds or longer and 10 minutes or shorter; and the heating temperature is, for example, 80° C. or higher and 140° C. or lower. Because the heating temperature is lower than the curing temperature of the resin layer precursor 16, the resin layer precursor 16 can be maintained uncured.

(2) As illustrated in FIG. 2(b), a support member 18, to both main surfaces of which first metal foils 19 (metal foils) are bonded, is prepared. To be specific, this is performed, for example, as follows.

First, the support member 18 and the first metal foils 19 are prepared. Next, the first metal foils 19 are bonded to both main surfaces of the support member 18. As a result, the support member 18, to both main surfaces of which the first metal foils 19 are bonded, can be prepared.

As the support member 18, for example, a print board, such as a glass epoxy circuit substrate covered with a glass cloth, can be used. A metal plate may be used as the support member 18. The support member 18, which supports the insulation layer 5 and the conductive layer 6 in the steps described below, has a larger thickness and a higher rigidity than the circuit substrate 3. The thickness of the support member 18 is, for example, 0.3 mm or larger and 1.2 mm or smaller. The Young's modulus of the support member 18 is, for example 10 GPa or higher and 200 GPa or lower. The thermal expansion coefficient of the support member 18 is, for example, 12 ppm/° C. or larger and 20 ppm/° C. or smaller.

A metal foil that can be used as the first metal foil 19 includes a first metal layer 20; a second metal layer 21, which is disposed on the first metal layer 20 and is made of a metal different from the first metal layer 20; and a third metal layer 22, which is disposed on the second metal layer 21 and is made of a metal the same as the first metal layer 20. The first metal layer 20 is made of, for example, copper or the like. The thickness of the first metal layer 20 is, for example, 1 μm or larger and 10 μm or smaller. The second metal layer 21 is made of, for example, chrome, nickel, cobalt, or an alloy of these metals. The thickness of the second metal layer 21 is, for example, 0.01 μm or larger and 3 μm or smaller. The third metal layer 22 is made of, for example, copper or the like. The thickness of the third metal layer 22 is, for example, 8 μm or larger and 30 μm or smaller.

The first metal foils 19 can be bonded to the support member 18 by using, for example, an adhesive made of epoxy resin or the like. In each first metal foil 19, the third metal layer 22 is bonded to the support member 18, and the first metal layer 20 is disposed on the side opposite to the support member 18 side and is exposed. A copper-clad laminate in which the first metal foils 19 are directly bonded to the support member 18 may be used as the support member 18 to both main surfaces of which the first metal foils 19 are bonded. The copper-clad laminate can be made by stacking the first metal foils 19 on both main surfaces of the support member 18, which includes an uncured resin; heating and pressing vertically the first metal foils 19 and the support member 18 at a temperature higher than or equal to the curing temperature and lower than the decomposition temperature of the uncured resin; and directly bonding the first metal foils 19 to the support member 18 while curing the resin.

In the present step, each of the first metal foils 19 is bonded to a corresponding one of the main surfaces of the support member 18. The steps described below are performed on each of the main surfaces of the support member 18.

(3) As illustrated in FIGS. 2(c) to 4(a), by alternately stacking the insulation layers 5 and the conductive layers 6 on the support member 18 via the first metal foil 19, the circuit substrate 3 is formed on the support member 18. To be specific, this is performed, for example, as follows.

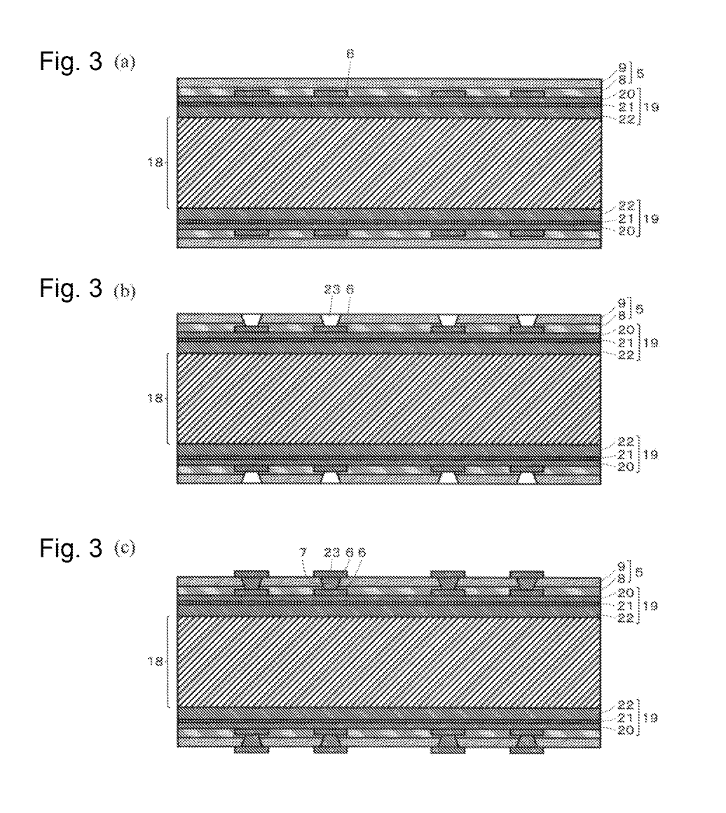

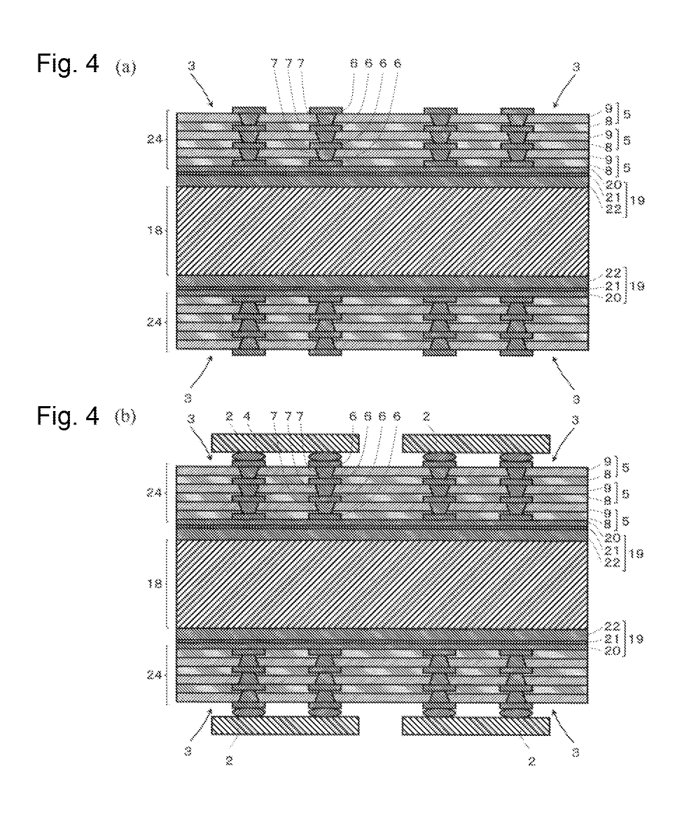

First, as illustrated in FIG. 2(c), the conductive layer 6 is partially formed on the first metal foil 19. Next, as illustrated in FIG. 2(d), by using the stack sheet 17 as described below, the insulation layer 5, which includes the resin layer 8 and the inorganic insulation layer 9, is formed on the first metal foil 19 and the conductive layer 6. Next, as illustrated in FIG. 3(a), the support sheet 15, which has been included in the stack sheet 17, is removed from the inorganic insulation layer 9. Next, as illustrated in FIG. 3(b), a via hole 23, which extends through the insulation layer 5 in the thickness direction and in which the conductive layer 6 is exposed, is formed. Next, as illustrated in FIG. 3(c), the via conductor 7 is formed in the via hole 23 while partially forming the conductive layer 6 on the insulation layer 5. Next, as illustrated in FIG. 4(a), the insulation layer 5, the conductive layer 6, and the via conductor 7 are repeatedly formed in the same way as described above. As a result, the circuit substrate 3 can be formed on the support member 18 by alternately stacking the insulation layer 5 and the conductive layer 6 on the support member 18 via the first metal foil 19.

The conductive layer 6 can be formed on the first metal foil 19, for example, as follows. First, a resist (not shown), which partially covers the first metal foil 19, is formed by photolithography. Next, by using an electrolytic plating method, the conductive layer 6 is formed on a part of the first metal foil 19 that is not covered by the resist. Next, the conductive layer 6 is formed by removing the resist from the first metal foil 19.

The conductive layer 6 may be formed without using an electrolytic plating method. In this case, the conductive layer 6 can be formed, for example, as follows. First, after forming a resist on the first metal foil 19, the first metal layer 20 of the first metal foil 19 is partially removed by using an etching solution, such as ferric chloride solution or copper chloride solution. Next, the conductive layer 6 is formed by removing the resist from the first metal foil 19.

The insulation layer 5 is formed on the first metal foil 19 and the conductive layer 6, for example, as follows. First, while disposing the resin layer precursor 16 of the stack sheet 17 on the conductive layer 6 side, the stack sheet 17 is stacked on the first metal foil 19 and the conductive layer 6. Next, the stack sheet 17 and the support member 18 are heated and pressed in the stacking direction at a temperature higher than or equal to the curing temperature of resin layer precursor 16. As a result, the resin layer precursor 16 is thermally cured and becomes the resin layer 8, and the resin layer 8 is bonded to the first metal foil 19 and the conductive layer 6 while embedding the conductive layer 6 in the resin layer 8. As described above, the insulation layer 5, which includes the resin layer 8 and the inorganic insulation layer 9 that has been included in the stack sheet 17, can be formed on the first metal foil 19 and the conductive layer 6. When heating and pressing the stack sheet 17 and the support member 18, the pressure is, for example, 0.5 MPa or higher and 2 MPa or lower; the pressing time is, for example, 60 seconds or longer and 10 minutes or shorter; and the heating temperature is, for example, 80° C. or higher and 170° C. or lower.

The support sheet 15 can be removed from the inorganic insulation layer 9 by, for example, mechanical peeling. In a case where the support sheet 15 is made of a metal foil, the support sheet 15 can be removed chemically by using an etching solution, such as ferric chloride solution or copper chloride solution.

The via hole 23 can be formed by, for example, laser processing using a YAG laser, a CO₂ laser, or the like. When laser processing is used, it is desirable to remove smear (residual resin), which is formed in the via hole 23 by laser processing, by performing a de-smearing treatment before forming the via conductor 7.

The conductive layer 6 can be formed on the insulation layer 5 and the via conductor 7 can be formed in the via hole 23 by using, for example, a semi-additive method, a subtractive method, and a full-additive method, or the like, which uses a plating method, such as a non-electrolytic plating method or an electrolytic plating method.

In the present embodiment, a multi-circuit substrate 24, which includes a plurality of circuit substrates 3, is formed on the support member 18. In other words, the circuit substrates 3 are simultaneously formed as one multi-circuit substrate 24 on the support member 18. The multi-circuit substrate 24 includes the circuit substrates 3 that are arranged, for example, in a matrix pattern. The multi-circuit substrate 24 is formed on each main surface of the support member 18.

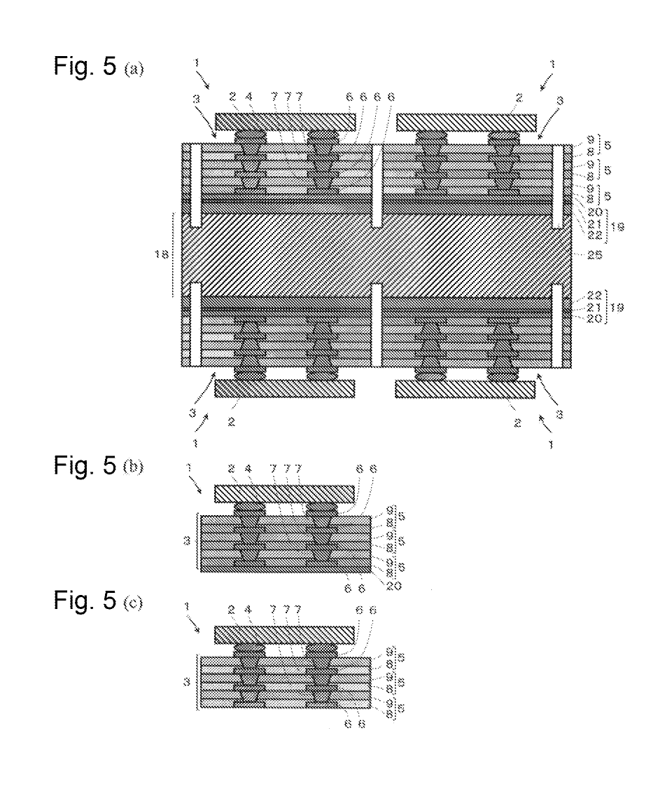

(4) As illustrated in FIGS. 4(b) and 5(a), a plurality of mounted structures 1, each including the circuit substrate 3 and the electronic component 2, are formed on the support member 18 by mounting the electronic components 2 on the circuit substrates 3. To be specific, this is performed, for example, as follows.

First, the electronic components 2 are prepared by cutting and dividing a wafer including a plurality of electronic components 2. Next, as illustrated in FIG. 4(b), the electronic components 2 are flip chip mounted on the multi-circuit substrate 24 via the bumps 4. At this time, in order to connect the multi-circuit substrate 24 and the electronic components 2 to each other via the bumps 4, reflow is performed at a temperature of, for example, 220° C. or higher and 270° C. or lower. Next, as illustrated in FIG. 5(a), by performing dicing, laser processing, or the like, parts of the multi-circuit substrate 24 between the circuit substrates 3 are cut from one main surface of the multi-circuit substrate 24 on the side opposite to the support member 18 side toward the other main surface on the support member 18 side. Thus, the multi-circuit substrate 24 can be divided into the circuit substrates 3 without dividing the support member 18. As a result, the mounted structures 1 can be formed on the support member 18.

In the present embodiment, when cutting the multi-circuit substrate 24, the support member 18 is not divided. As a result, the mounted structures 1 are disposed on the single support member 18, so that the mounted structures 1 can be handled easily.

In the present embodiment, when cutting the multi-circuit substrate 24, not only the multi-circuit substrate 24 but also the first metal foils 19 are cut and divided. As a result, in step (5) described below, the support member 18 can be easily removed from the multi-circuit substrate 24.

In the present embodiment, when cutting the multi-circuit substrate 24, cuts 25 are formed by cutting not only the multi-circuit substrate 24 and the first metal foils 19 but also parts of the support member 18 near both main surfaces of the support member 18. At this time, a central portion of the support member 18 in the thickness direction is not cut and the support member 18 is not divided. As a result, even if the cutting depth varies, the multi-circuit substrate 24 and the first metal foils 19 can be cut and divided without fail. The depths of the cuts 25 are, for example, 0.2 times or larger and 0.4 times or smaller of the thickness of the support member 18.

(5) As illustrated in FIGS. 5(b) and 5(c), the support member 18 is removed from the mounted structure 1. To be specific, this is performed, for example, as follows.

First, as illustrated in FIG. 5(b), the mounted structure 1 and the support member 18 are mechanically peeled from each other by applying a mechanical stress to the mounted structure 1 and the support member 18. At this time, the first metal layer 20 and the second metal layer 21 are peeled from each other, because the first metal layer 20 and the second metal layer 21, which are made of different metals, can be easily peeled at an interface therebetween. As a result, the second metal layer 21 can be removed from the mounted structure 1, and the support member 18 can be removed from the mounted structure 1. Next, as illustrated in FIG. 5(c), the first metal layer 20 is removed from the mounted structure 1 by using an etching solution, such as ferric chloride solution or copper chloride solution.

Thus, the mounted structure 1 shown in FIG. 1 can be made.

The method for producing the mounted structure 1 according to the present embodiment described above includes a step of forming the circuit substrate 3, which includes the insulation layer 5 and the conductive layer 6, on the support member 18 by alternately stacking the insulation layer 5 and the conductive layer 6 on the support member 18; a step of forming the mounted structure 1, which includes the circuit substrate 3 and the electronic component 2, on the support member 18 by mounting the electronic component 2 on the circuit substrate 3; and a step of removing the support member 18 from the mounted structure 1.

As a result, after forming the mounted structure 1 on the support member 18, the support member 18 is removed from the mounted structure. Therefore, for example, as compared with a case where the electronic component 2 is mounted on the circuit substrate from which the support member 18 has been removed, the warping of the circuit substrate 3 can be suppressed when mounting the electronic component 2 on the circuit substrate 3. As a result, the occurrence of a faulty electrical connection between the circuit substrate 3 and the electronic component 2 can be reduced, and the efficiency in producing the mounted structure 1 can be increased. In particular, in a case where the thickness of the circuit substrate 3 is reduced, the circuit substrate 3 tends to become warped more easily. Even in such a case, the warping of the circuit substrate 3 can be suppressed. Therefore, for example, a thin circuit substrate 3 having a thickness of 100 μm or smaller can be formed.

Moreover, forming of the circuit substrate 3 and mounting of the electronic component 2 on the circuit substrate 3 are both performed on the support member 18. Therefore, for example, as compared with a case where the electronic component 2 is mounted on the circuit substrate 3 from which the support member 18 has been removed, the circuit substrate 3 can be easily handled by using the support member 18. Accordingly, the occurrence of a fault due to mechanical damage during handling can be reduced, and the efficiency in producing the mounted structure 1 can be increased. In particular, as the thickness of the circuit substrate 3 is reduced, it tends to become more difficult to handle the circuit substrate 3 in the production process. Even in such a case, the circuit substrate 3 can be easily handled.

In the present embodiment, in the step of forming the circuit substrate 3 on the support member 18, the multi-circuit substrate 24, which includes the plurality of circuit substrates 3, is formed on the support member 18. Moreover, in the step of forming the mounted structure 1 on the support member 18, after mounting the plurality of electronic components 2 on the multi-circuit substrate 24, by dividing the multi-circuit substrate 24 into the circuit substrates 3, the plurality of mounted structures 1, each of which includes the circuit substrate 3 and the electronic component 2, are formed on the support member 18. As a result, the circuit substrates 3 and the mounted structures 1 can be simultaneously formed, so that the efficiency in producing the mounted structure 1 can be increased. Moreover, because mounting of the electronic components 2 is performed on the multi-circuit substrate 24, which includes the circuit substrates 3, handling of the circuit substrate 3 can be made easy, and the efficiency in producing the mounted structure 1 can be increased.

In the present embodiment, in the step of forming the circuit substrate 3 on the support member 18, the insulation layer 5, which includes the resin layer 8, and the conductive layer 6 are alternately stacked on the support member 18. As a result, as compared with a case where the insulation layer 5 is made from a ceramic layer, it is not necessary to perform a step of firing the ceramic layer at a temperature of, for example, 1200° C. or higher. Therefore, the circuit substrate 3 can be formed by alternately stacking the insulation layer 5 and the conductive layer 6 on the support member 18, and further the electronic component 2 can be mounted on the circuit substrate 3 on the support member 18. As a result, the circuit substrate 3 can be easily handled. On the other hand, as compared with a case where the insulation layer 5 is made from a ceramic layer, the insulation layer 5 including the resin layer 8 is likely to have a low rigidity and a high thermal expansion coefficient, and therefore the circuit substrate 3 may become warped easily. However, in the present embodiment, as described above, the warping of the circuit substrate 3 can be effectively suppressed by using the support member 18.

In the present embodiment, in the step of forming the circuit substrate 3 on the support member 18, the insulation layer 5, which further includes the inorganic insulation layer 9, and the conductive layer 6 are alternately stacked on the support member, the inorganic insulation layer 9 including the plurality of inorganic insulation particles 12 and 13 whose parts are connected to each other and a part of the resin layer 8 being disposed in the gap 14 between the inorganic insulation particles. 12 and 13. As a result, the inorganic insulation layer 9, which has a higher rigidity and a lower thermal expansion coefficient than the resin layer 8, can suppress the warping of the circuit substrate 3. Moreover, because the inorganic insulation layers 9 are bonded to each other with the resin layer 8 therebetween, as compared with a case where the insulation layer 5 is made from a ceramic layer, for example, it is not necessary to perform a step of firing the ceramic layer at a temperature of, for example, 1200° C. or higher. Therefore, the insulation layer 5 including the inorganic insulation layer 9 can be stacked on the support member 18. Furthermore, because a part of the resin layer 8 is disposed in the gap 14, the bonding strength of the resin layer 8 and the inorganic insulation layer 9 can be increased.

In the present embodiment, in the step of forming the circuit substrate 3 on the support member 18, the insulation layer 5, which includes the inorganic insulation layer 9 disposed on the side opposite to the support member 18 side and the resin layer 8 disposed on the support member 18 side, and the conductive layer 6 are alternately stacked on the support member 18. As a result, in the insulation layer 5 adjacent to the electronic component 2, the inorganic insulation layer 9 is disposed on the electronic component 2 side. Therefore, the difference in thermal expansion coefficient between the electronic component 2 and the insulation layer 5 adjacent to the electronic component 2 can be reduced, and thereby the occurrence of a faulty connection between the circuit substrate 3 and the electronic component 2 can be reduced.

In the present embodiment, in the step of forming the circuit substrate 3 on the support member 18, the insulation layer 5 and the conductive layer 6, which is formed on the insulation layer 5 by using a plating method, are alternately stacked on the support member 18. As a result, the conductive layer 6 can be easily formed on the support member 18.

In the present embodiment, in the step of forming the circuit substrate 3 on the support member 18, the insulation layer 5 and the conductive layer 6 are alternately stacked on the support member 18 with the first metal foil 19 therebetween. The first metal foil 19 includes the first metal layer 20 and the second metal layer 21, which is disposed on the support member 18 side of the first metal layer 20 and which is made of a metal different from the first metal layer 20. Moreover, in the step of removing the support member 18 from the mounted structure 1, after removing the support member 18 from the mounted structure 1 by removing the second metal layer 21 from the mounted structure 1, the first metal layer 20 is removed from the mounted structure 1. As a result, because the first metal foil 19 is used to remove the support member 18 from the mounted structure 1, when mounting of the electronic component 2 on the circuit substrate 3, for example, as compared with a case where a special resin or the like is used, it is not likely that bulging of the first metal foil 19 occurs. Therefore, the occurrence of a faulty connection between the circuit substrate 3 and the electronic component 2 can be reduced.

In the present embodiment, on each main surface of the support member 18, the circuit substrate 3 is formed and the electronic component 2 is mounted on the circuit substrate 3. As a result, because the circuit substrates 3 are formed on both main surfaces of the support member 18, the number of circuit substrates 3 formed in a single production process can be increased and the efficiency in producing the mounted structure 1 can be increased. Moreover, the circuit substrates 3 are disposed at positions that are line-symmetric about the support member 18. Therefore, if heat is applied to the support member 18 and the circuit substrate 3 when mounting the electronic component 2 on the circuit substrate 3, application of a nonuniform thermal stress to the support member 18 can be suppressed. Thus, the warping of the support member 18 can be suppressed, and the occurrence of a faulty connection between the circuit substrate 3 and the electronic component 2 can be reduced.

Preferably, in the present embodiment, in the step of forming the mounted structure 1 on the support member 18, after mounting the electronic components 2 on the multi-circuit substrate 24, the electronic components 2 are sealed with a sealing resin. Preferably, in the step of forming the mounted structure 1 on the support member 18, by simultaneously cutting the multi-circuit substrate 24 and the sealing resin, the multi-circuit substrate 24 is divided into the circuit substrates 3. As a result, as compared with a case where the electronic components 2 of the mounted structures 1 are individually sealed with a sealing resin after making the mounted structures 1, the efficiency in producing the mounted structure 1 can be increased.

Preferably, in the present embodiment, the support member 18 has a larger thickness and a higher rigidity than the circuit substrate 3. As a result, the warping of the circuit substrate 3 can be effectively suppressed and the circuit substrate 3 can be more easily handled.

Preferably, in the present embodiment, the electronic component 2 is an elastic wave device. In general, elastic wave devices have areas in plan view smaller than those of semiconductor devices. Therefore, the area of the mounted structure 1 in plan view can be reduced, and thereby the support member 18 can be easily removed from the mounted structure 1. In the case where the electronic component 2 is an elastic wave device, the area of the electronic component 2 in plan view is, for example, 0.5 mm² or larger and 9 mm² or smaller.

### Second Embodiment

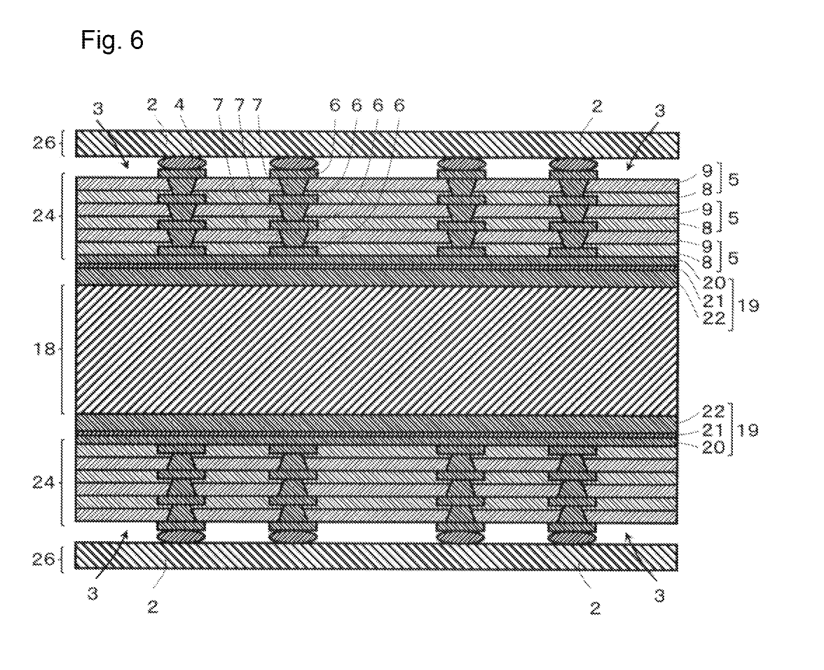

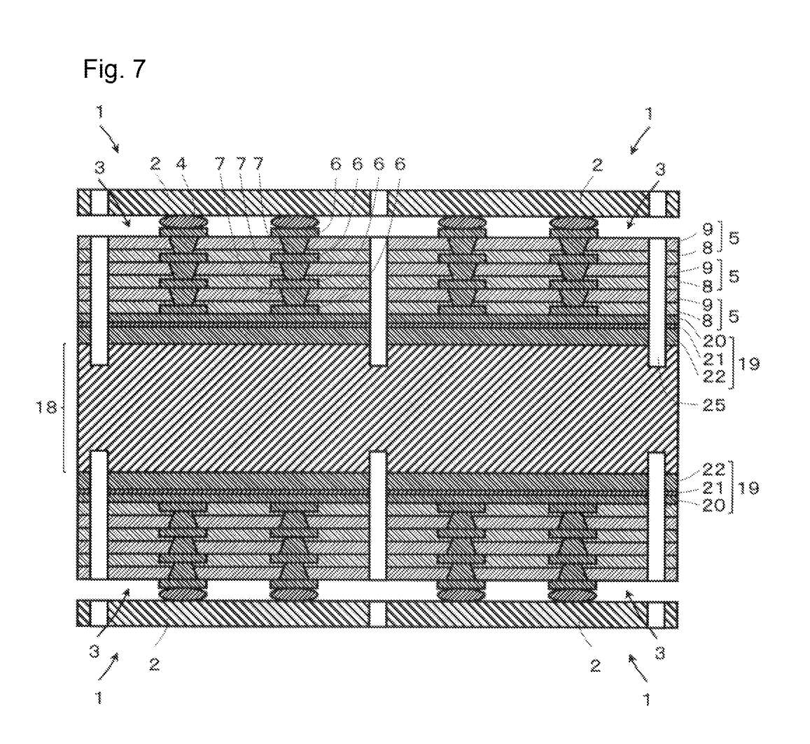

Next, referring to FIGS. 6 and 7, a method for producing a mounted structure according to a second embodiment of the present invention will be described in detail. Descriptions of elements the same as those of the first embodiment will be omitted.

A method for producing a mounted structure 1 according to the second embodiment differs from the method according to the first embodiment in that a wafer 26 including a plurality of electronic components 2 is mounted on the circuit substrate 3 in step (4).

In other words, as illustrated in FIG. 6, in the present embodiment, in the step of forming the mounted structure 1 on the support member 18, after mounting the wafer 26, which includes the electronic components 2, on the multi-circuit substrate 24, as illustrated in FIG. 7, the multi-circuit substrate 24 is divided into the circuit substrates 3 while the wafer 26 is divided into the electronic components 2.

As a result, because the electronic components 2 can be simultaneously mounted on the circuit substrate 3 by mounting the wafer 26 on the multi-circuit substrate 24, the efficiency in producing the mounted structure 1 can be increased. As compared with a case where the electronic components 2 are individually handled, the wafer 26 can be easily handled because it has a large area. Accordingly, the occurrence of a fault due to mechanical damage during handling can be reduced. Moreover, because the warping of the multi-circuit substrate 24 can be effectively suppressed by the support member 18, the occurrence of a faulty connection when mounting the wafer 26 on the multi-circuit substrate 24 can be reduced.

As illustrated in FIG. 7, in the present embodiment, in the step of forming the mounted structure 1 on the support member 18, by simultaneously cutting the wafer 26 and the multi-circuit substrate 24, the multi-circuit substrate 24 is divided into the circuit substrates 3 while the wafer 26 is divided into the electronic components 2. As a result, because the wafer 26 and the multi-circuit substrate 24 are simultaneously cut, as compared with the first embodiment, the number of cutting operations can be reduced and the efficiency in producing the mounted structure 1 can be increased. In the mounted structure 1 obtained by using this method, an end surface of the circuit substrate 3 and an end surface of the electronic component 2 are located in the same plane.

Preferably, in the present embodiment, in the step of forming the mounted structure 1 on the support member 18, after mounting the wafer 26, which includes the electronic components 2, on the multi-circuit substrate 24, the wafer 26 is sealed with a sealing resin; and, in the step of forming the mounted structure 1 on the support member 18, the wafer 26, the multi-circuit substrate 24, and the sealing resin are simultaneously cut. As a result, as compared with a case where the mounted structures 1 are individually sealed with a sealing resin after making the mounted structures 1, the efficiency in producing the mounted structure 1 can be increased.

The wafer 26 includes the electronic components 2 arranged, for example, in a matrix pattern. The electronic components 2 of the wafer 26 and the circuit substrates 3 of the multi-circuit substrate 24 are formed at corresponding positions.

### Third Embodiment

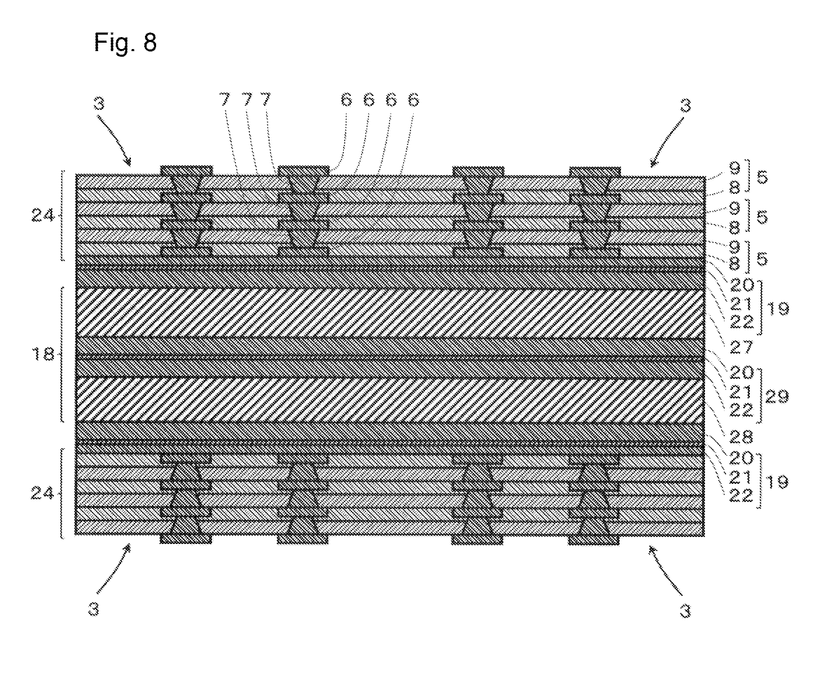

Next, referring to FIGS. 8 to 10, a method for producing a mounted structure according to a third embodiment of the present invention will be described in detail. Descriptions of elements the same as those of the first embodiment will be omitted.

A method for producing a mounted structure 1 according to the third embodiment differs from the first embodiment in that the support member 18 includes a first support portion 27 and a second support portion 28.

In other words, as illustrated in FIG. 8, in the present embodiment, in the step of forming the circuit substrate 3 on the support member 18, which includes the first support portion 27 and the second support portion 28 stacked on the first support portion 27, by alternately stacking the insulation layer 5 and the conductive layer 6 on each of the first support portion 27 and the second support portion 28, the circuit substrate 3 is formed on each of the first support portion 27 and the second support portion 28 of the support member 18.

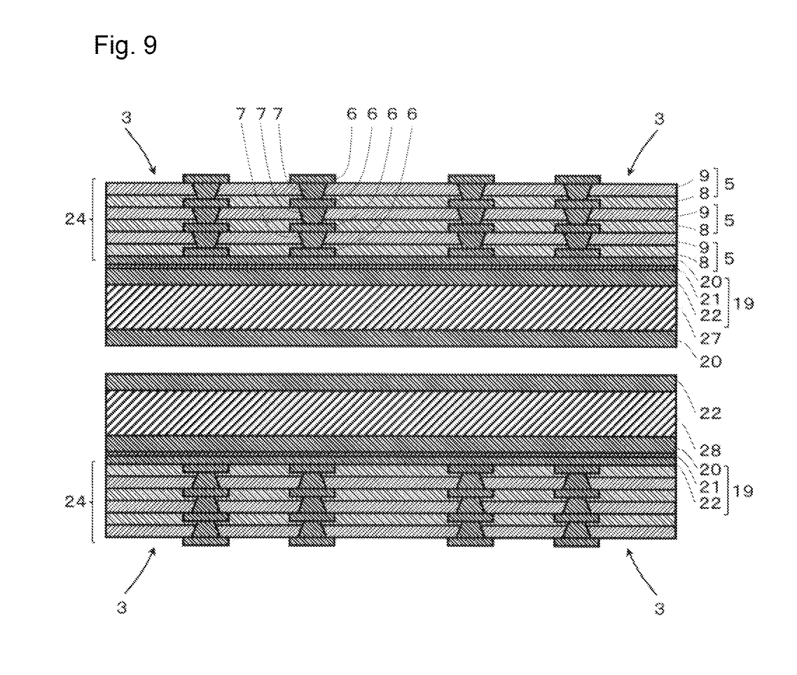

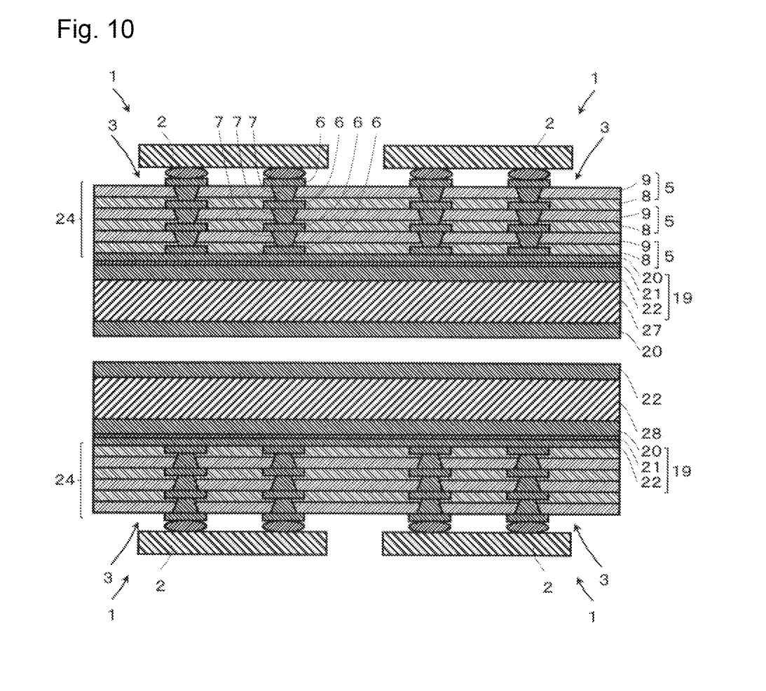

Moreover, as illustrated in FIGS. 9 and 10, in the step of forming the mounted structure 1 on the support member 18, after peeling the first support portion 27 and the second support portion 28 from each other, by mounting the electronic component 2 on each of the circuit substrate 3 on the first support portion 27 and the circuit substrate 3 on the second support portion 28, the mounted structure 1 is formed on each of the first support portion 27 and the second support portion 28. In the step of removing the support member 18 from the mounted structure 1, the first support portion 27 or the second support portion 28 is removed from the mounted structure 1.

As a result, in the step of forming the circuit substrate 3 on the support member 18, because the circuit substrates 3 are formed on both main surfaces of the support member 18, the number of circuit substrates 3 formed in a single production process can be increased and the efficiency in producing the mounted structure 1 can be increased. Moreover, in the step of forming the mounted structure 1 on the support member 18, after peeling the first support portion 27 and the second support portion 28 from each other, the electronic component 2 is mounted on each of the circuit substrate 3 on the first support portion 27 and the circuit substrate 3 on the second support portion 28. Therefore, as compared with the first embodiment, handling of the circuit substrate 3 and the electronic component 2 during the mounting operation can be made easy, and the electronic component 2 can be easily mounted on the circuit substrate 3.

The first support portion 27 and the second support portion 28 of the present embodiment have the same structures and characteristics as the support member 18 of the first embodiment. The thickness of the first support portion 27 and the thickness of the second support portion 28 are each, for example, 0.2 mm or larger and 1 mm or smaller. The support member 18 may further include a third support portion between the first support portion 27 and the second support portion 28.

As illustrated in FIG. 8, the support member 18 of the present embodiment further includes a second metal foil 29 between the first support portion 27 and the second support portion 28. The second metal foil 29 has the same structure as the first metal foil 19 of the first embodiment and includes the first metal layer 20, the second metal layer 21, and the third metal layer 22. The first metal layer 20 of the second metal foil 29 is bonded to the first support portion 27, and the third metal layer 22 of the second metal foil 29 is bonded to the second support portion 28.

As illustrated in FIG. 9, the first support portion 27 and the second support portion 28 can be peeled from each other by applying a mechanical stress to the first support portion 27 and the second support portion 28, and thereby peeling the first metal layer 20 and the second metal layer 21 from each other and peeling the second metal layer 21 and the third metal layer 22 from each other.

The present invention is not limited to the embodiments described above. Any modification, improvement, and combination can be made within the sprit and scope of the present invention.

In the embodiments of the present invention described above, the electronic component 2 is flip chip mounted on the circuit substrate 3. However, the electronic component 2 may be mounted on the circuit substrate 3 by wire bonding.

In the embodiments of the present invention described above, the circuit substrate 3 includes three insulation layers 5 and four conductive layers 6. However, the circuit substrate 3 may include any number of insulation layers 5 and conductive layers 6. Preferably, the circuit substrate 3 includes two insulation layers 5 and three conductive layers 6. As a result, the thickness of the circuit substrate 3 can be reduced by reducing the numbers of the insulation layers 5 and the conductive layers 6.

In the embodiments of the present invention described above, the insulation layer 5 includes the resin layer 8 and the inorganic insulation layer 9. However, the insulation layer 5 may include only the resin layer 8. The insulation layer 5 may further include an interposed resin layer (primer layer), which is disposed on one main surface of the inorganic insulation layer 9 on the side opposite to the resin layer 8 side and which is interposed between the inorganic insulation layer 9 and the conductive layer 6.

In the embodiments of the present invention described above, the inorganic insulation layer 9 includes the first inorganic insulation particles 12 and the second inorganic insulation particles 13. However, the inorganic insulation layer 9 may include only the first inorganic insulation particles 12 or may include other inorganic insulation particles.

In the embodiments of the present invention described above, in step (1), evaporation of the solvent 26 and heating of the inorganic insulation particles 12 and 13 are independently performed. However, these may be simultaneously performed.

In the embodiments of the present invention described above, in step (2), the first metal foil 19 includes the first metal layer 20, the second metal layer 21, and the second metal layer 22. However, the first metal foil 19 may include only the first metal layer 20.

In the embodiments of the present invention described above, in step (3), the insulation layers 5 and the conductive layers 6 are alternately stacked on the support member 18 via the first metal foil 19. However, the insulation layers 5 and the conductive layers 6 may be alternately stacked on the support member 18 without using the first metal foil 19. In this case, preferably, the insulation layers 5 and the conductive layers 6 are alternately stacked on the support member 18 via a resin film made of fluorocarbon resin or the like.

In the embodiments of the present invention described above, in step (3), the circuit substrate 3 is formed on each main surface of the support member 18. However, the circuit substrate 3 may be formed on only one main surface of the support member 18.

In the embodiments of the present invention described above, in step (3), the multi-circuit substrate 24, which includes the circuit substrates 3, is formed on the support member 18. However, the circuit substrates 3 may be independently formed on the support member 18.

### REFERENCE SIGNS LIST

1 mounted structure
2 electronic component
3 circuit substrate
4 bump
5 insulation layer
6 conductive layer
7 via conductor
8 resin layer
9 inorganic insulation layer
10 resin
11 filler particle
12 first inorganic insulation particle
13 second inorganic insulation particle
14 gap
15 support sheet
16 resin layer precursor
17 stack sheet
18 support member
19 first metal foil
20 first metal layer
21 second metal layer
22 third metal layer
23 via hole
24 multi-circuit substrate
25 cut
26 wafer
27 first support portion
28 second support portion
29 second metal foil

1. A method for producing a mounted structure, comprising:
a step of forming a circuit substrate, which includes an insulation layer and a conductive layer, on a support member by alternately stacking the insulation layer and the conductive layer on the support member;
a step of forming a mounted structure, which includes the circuit substrate and an electronic component, on the support member by mounting the electronic component on the circuit substrate; and
a step of removing the support member from the mounted structure.

2. The method for producing a mounted structure according to claim 1,
wherein, in the step of forming the circuit substrate on the support member,
a multi-circuit substrate, which includes a plurality of the circuit substrates, is formed on the support member, and
wherein, in the step of forming the mounted structure on the support member,
after mounting a plurality of the electronic components on the multi-circuit substrate, by dividing the multi-circuit substrate into the circuit substrates, a plurality of the mounted structures, each of which includes the circuit substrate and the electronic component, are formed on the support member.

3. The method for producing a mounted structure according to claim 2,
wherein, in the step of forming the mounted structure on the support member,
after mounting a wafer, which includes the electronic components, on the multi-circuit substrate, the multi-circuit substrate is divided into the circuit substrates while the wafer is divided into the electronic components.

4. The method for producing a mounted structure according to claim 3,
wherein, in the step of forming the mounted structure on the support member,
by simultaneously cutting the wafer and the multi-circuit substrate, the multi-circuit substrate is divided into the circuit substrates while the wafer is divided into the electronic components.

5. The method for producing a mounted structure according to claim 1,
wherein, in the step of forming the circuit substrate on the support member,
the insulation layer, which includes a resin layer, and the conductive layer are alternately stacked on the support member.

6. The method for producing a mounted structure according to claim 5,
wherein, in the step of forming the circuit substrate on the support member,
the insulation layer, which further includes an inorganic insulation layer, and the conductive layer are alternately stacked on the support member, the inorganic insulation layer including a plurality of inorganic insulation particles whose parts are connected to each other and a part of the resin layer being disposed in a gap between the inorganic insulation particles.

7. The method for producing a mounted structure according to claim 6,
wherein, in the step of forming the circuit substrate on the support member,
the insulation layer which includes the inorganic insulation layer and the resin layer that is disposed on the support member side of the inorganic insulation layer, and the conductive layer are alternately stacked on the support member.

8. The method for producing a mounted structure according to claim 1,
wherein, in the step of forming the circuit substrate on the support member,
the insulation layer and the conductive layer, which is formed on the insulation layer by using a plating method, are alternately stacked on the support member.

9. The method for producing a mounted structure according to claim 1,
wherein, in the step of forming the circuit substrate on the support member,
the insulation layer and the conductive layer are alternately stacked on the support member with a metal foil therebetween, the metal foil including a first metal layer and a second metal layer that is disposed on the support member side of the first metal layer and that is made of a metal different from the first metal layer, and
wherein, in the step of removing the support member from the mounted structure,
after removing the support member from the mounted structure by removing the second metal layer from the mounted structure, the first metal layer is removed from the mounted structure.

10. The method for producing a mounted structure according to claim 1,
wherein, in the step of forming the circuit substrate on the support member,
by alternately stacking the insulation layer and the conductive layer on each of a first support portion and a second support portion of the support member including the first support portion and the second support portion stacked on the first support portion, the circuit substrate, which includes the insulation layer and the conductive layer, is formed on each of the first support portion and the second support portion of the support member,
wherein, in the step of forming the mounted structure on the support member,
after peeling the first support portion and the second support portion from each other, by mounting the electronic component on each of the circuit substrate on the first support portion and the circuit substrate on the second support portion, the mounted structure, which includes the circuit substrate and the electronic component, is formed on each of the first support portion and the second support portion, and
wherein, in the step of removing the support member from the mounted structure,
the first support portion or the second support portion is removed from the mounted structure.

11. The method for producing a mounted structure according to claim 1,
wherein, in the step of forming the mounted structure on the support member,
the electronic component, which is an elastic wave device, is mounted on the circuit substrate.
